(19) United States
(12) Patent Application Publication
(10) Pub. No.: US 2026/0150439 A1
(43) Pub. Date: May 28, 2026

(54) DUAL-BAND LIGHT EMITTING DIODE AND MANUFACTURING METHOD THEREOF

(71) Applicant: Taiwan-Asia Semiconductor Corporation, Hsinchu City (TW)

(72) Inventors: Ching-Yuan Tsai, Hsinchu City (TW); Hong-Ta Cheng, Hsinchu City (TW); Chuan-Wei Chen, Hsinchu City (TW)

(21) Appl. No.: 19/188,829

(22) Filed: Apr. 24, 2025

(30) Foreign Application Priority Data
Nov. 22, 2024 (TW) 113145074

(51) Int. Cl. H10H 20/833; H10H 20/01; H10H 20/821; H10H 20/824

(52) U.S. Cl. CPC H10H 20/833; H10H 20/013; H10H 20/8242; H10H 20/821

(57) ABSTRACT

A dual-band light-emitting diode and a manufacturing method thereof are provided. The dual-band light-emitting diode comprises a first epitaxial composite layer, a second epitaxial composite layer and a transparent conductive layer. The first epitaxial composite layer has a first light-emitting layer of a first wavelength band, the second epitaxial composite layer has a second light-emitting layer of a second wavelength band, and the first wavelength band is no less than the second wavelength band. The transparent conductive layer is interposed between the first epitaxial composite layer and the second epitaxial composite layer, and the first epitaxial composite layer is disposed on the second epitaxial composite layer.

CROSS-REFERENCES TO RELATED APPLICATIONS

This application claims the benefit of priority to Taiwanese Patent Application No. 113145074 filed on Nov. 22, 2024, which is hereby incorporated by reference in its entirety.

### BACKGROUND OF THE INVENTION

### Field of the Invention

The present invention relates to a dual-band light-emitting diode and a manufacturing method thereof, and in particular to a dual-band short-wavelength infrared light-emitting diode and a manufacturing method thereof.

### Descriptions of the Related Art

A light-emitting diode (LED) offers advantages such as high brightness, small size, low power consumption, and long lifespan, making it widely used in lighting or display products. Recently, LEDs have begun to be incorporated into wearable devices. For example, in wearable devices, LEDs are utilized for non-invasive blood glucose detection for sparing users the discomfort of long-term invasive blood glucose monitoring.

Taking blood glucose detection as an example, several LED chips operating in the short-wavelength infrared (SWIR) range have been integrated into blood glucose detection modules. Examples include LED chips with wavelengths of 1065 nanometers (nm), 1350 nanometers (nm), and 1450 nanometers (nm). To improve measurement accuracy, blood glucose monitoring modules have started incorporating two or more wavelength bands in a single module. By using LEDs with different wavelengths, these modules can address the varying absorption characteristics of skin and blood for different wavelength bands for thereby enhancing detection sensitivity.

Common multi-band blood glucose detection modules pair a 1065 nm wavelength LED chip with a 1350 nm wavelength LED chip, or a 1065 nm wavelength LED chip with a 1450 nm wavelength LED chip. However, the 1065 nm wavelength LED can only be epitaxially grown on a gallium arsenide (GaAs) substrate. In contrast, LEDs for the wavelength bands of 1350 nm and 1450 nm require an indium phosphide (InP) substrate for epitaxial growth. As a result, LED packaging in multi-band blood glucose detection modules must integrate at least two different wavelength chips, and thus, increase the packaging space to accommodate multiple LED chips. In view of this, the industry urgently needs an innovative light-emitting diode structure and manufacturing method to meet the demands of wearable devices for both compactness and accuracy.

### SUMMARY OF THE INVENTION

The main objective of the present invention is to provide a high-brightness dual-band light-emitting diode and its manufacturing method, capable of simultaneously providing two short-wavelength infrared bands within a single light-emitting diode structure. This reduces the packaging volume of the light-emitting diode for meeting the requirements of wearable devices for compactness and precise detection.

To achieve the above objective, the present invention provides a dual-band light-emitting diode comprising a first epitaxial composite layer, a second epitaxial composite layer, and a transparent conductive layer. The first epitaxial composite layer has a first light-emitting layer of a first wavelength band, the second epitaxial composite layer has a second light-emitting layer of a second wavelength band, and the first wavelength band is no less than the second wavelength band. The transparent conductive layer is interposed between the first epitaxial composite layer and the second epitaxial composite layer, with the first epitaxial composite layer disposed on the second epitaxial composite layer.

In one embodiment of the dual-band light-emitting diode of the present invention, the dual-band light-emitting diode further comprises a P-type electrode disposed on the transparent conductive layer and electrically connected to the transparent conductive layer.

In one embodiment of the dual-band light-emitting diode of the present invention, the dual-band light-emitting diode further comprises a first N-type electrode and a second N-type electrode, wherein the first N-type electrode is disposed on the first epitaxial composite layer and electrically connected to the first light-emitting layer, and the second N-type electrode is disposed on the second epitaxial composite layer and electrically connected to the second light-emitting layer.

In one embodiment of the dual-band light-emitting diode of the present invention, the first epitaxial composite layer further comprises an N-type indium phosphide epitaxial layer and a P-type indium phosphide epitaxial layer, with the first light-emitting layer interposed between the N-type indium phosphide epitaxial layer and the P-type indium phosphide epitaxial layer.

In one embodiment of the dual-band light-emitting diode of the present invention, the first epitaxial composite layer further comprises a P-type zinc-doped indium gallium arsenide epitaxial layer interposed between the P-type indium phosphide epitaxial layer and the transparent conductive layer.

In one embodiment of the dual-band light-emitting diode of the present invention, the second epitaxial composite layer further comprises an N-type aluminum gallium arsenide epitaxial layer and a P-type aluminum gallium arsenide epitaxial layer, with the second light-emitting layer interposed between the N-type aluminum gallium arsenide epitaxial layer and the P-type aluminum gallium arsenide epitaxial layer.

In one embodiment of the dual-band light-emitting diode of the present invention, the second epitaxial composite layer further comprises a P-type carbon-doped gallium arsenide epitaxial layer interposed between the P-type aluminum gallium arsenide epitaxial layer and the transparent conductive layer.

In one embodiment of the dual-band light-emitting diode of the present invention, the first wavelength band is 1100˜2000 nanometers (nm), and the second wavelength band is 1000˜1100 nanometers (nm).

In one embodiment of the dual-band light-emitting diode of the present invention, the thickness of the transparent conductive layer is 3000˜10000 angstroms (Å).

To achieve the above objective, the present invention provides a manufacturing method for a dual-band light-emitting diode, comprising the following steps. First, provide a first epitaxial composite layer on a first epitaxial growth substrate, the first epitaxial composite layer having a first light-emitting layer of a first wavelength band. Second, provide a first transparent conductive layer on the first epitaxial composite layer. Third, provide a second epitaxial composite layer on a second epitaxial growth substrate, the second epitaxial composite layer having a second light-emitting layer of a second wavelength band, wherein the first wavelength band is no less than the second wavelength band. Fourth, provide a second transparent conductive layer on the second epitaxial composite layer. Finally, bond the first transparent conductive layer and the second transparent conductive layer, such that the first transparent conductive layer and the second transparent conductive layer are interposed between the first epitaxial composite layer and the second epitaxial composite layer, with the first epitaxial composite layer disposed on the second epitaxial composite layer.

In one embodiment of the manufacturing method of the dual-band light-emitting diode of the present invention, the method further comprises performing a mesa etching on the first epitaxial composite layer to expose a portion of the first transparent conductive layer after removing the first epitaxial growth substrate.

In one embodiment of the manufacturing method of the dual-band light-emitting diode of the present invention, the method further comprises providing a P-type electrode disposed on the exposed first transparent conductive layer and electrically connected to the first transparent conductive layer and the second transparent conductive layer.

In one embodiment of the manufacturing method of the dual-band light-emitting diode of the present invention, the method further comprises a step of providing a first N-type electrode disposed on the first epitaxial composite layer and electrically connected to the first light-emitting layer.

In one embodiment of the manufacturing method of the dual-band light-emitting diode of the present invention, the method further comprises a step of thinning the second epitaxial growth substrate.

In one embodiment of the manufacturing method of the dual-band light-emitting diode of the present invention, the method further comprises a step of providing a second N-type electrode disposed on the thinned second epitaxial growth substrate and electrically connected to the second light-emitting layer.

In one embodiment of the manufacturing method of the dual-band light-emitting diode of the present invention, the step of providing a first epitaxial composite layer formed on a first epitaxial growth substrate comprises a step of sequentially providing an N-type indium phosphide epitaxial layer, the first light-emitting layer, and a P-type indium phosphide epitaxial layer on an indium phosphide substrate.

In one embodiment of the manufacturing method of the dual-band light-emitting diode of the present invention, the step of providing a second epitaxial composite layer formed on a second epitaxial growth substrate comprises a step of sequentially providing an N-type aluminum gallium arsenide epitaxial layer, the second light-emitting layer, and a P-type aluminum gallium arsenide epitaxial layer on a gallium arsenide substrate.

In one embodiment of the manufacturing method of the dual-band light-emitting diode of the present invention, the first wavelength band is 1100˜2000 nanometers (nm), and the second wavelength band is 1000˜1100 nanometers (nm).

In one embodiment of the manufacturing method of the dual-band light-emitting diode of the present invention, the total thickness of the first transparent conductive layer and the second transparent conductive layer after bonding is 3000˜10000 angstroms (Å).

After referring to the drawings and the embodiments described subsequently, those skilled in the art will understand the other objectives of the present invention, as well as the technical means and embodiments of the present invention.

### BRIEF DESCRIPTION OF THE DRAWINGS

FIG. 1A to FIG. 1C illustrate schematic diagrams of manufacturing a light-emitting diode structure with a first wavelength band according to an embodiment of the present invention;

FIG. 2A to FIG. 2B illustrate schematic diagrams of manufacturing a light-emitting diode structure with a second wavelength band according to an embodiment of the present invention;

FIG. 3A to FIG. 3G illustrate schematic diagrams of manufacturing a dual-band light-emitting diode according to an embodiment of the present invention;

FIG. 4 is a top-view schematic diagram of a dual-band light-emitting diode according to an embodiment of the present invention; and

FIG. 5 is a schematic diagram of the process steps for manufacturing a dual-band light-emitting diode according to an embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

The present invention discloses a dual-band light-emitting diode and its manufacturing method, aimed at accommodating two independently operable light-emitting diodes within the same package body to individually or collectively provide light in different wavelength ranges for subsequent application modules. Therefore, the present invention will specifically describe, through the embodiments below, how to integrate two independent light-emitting diodes into a single package body.

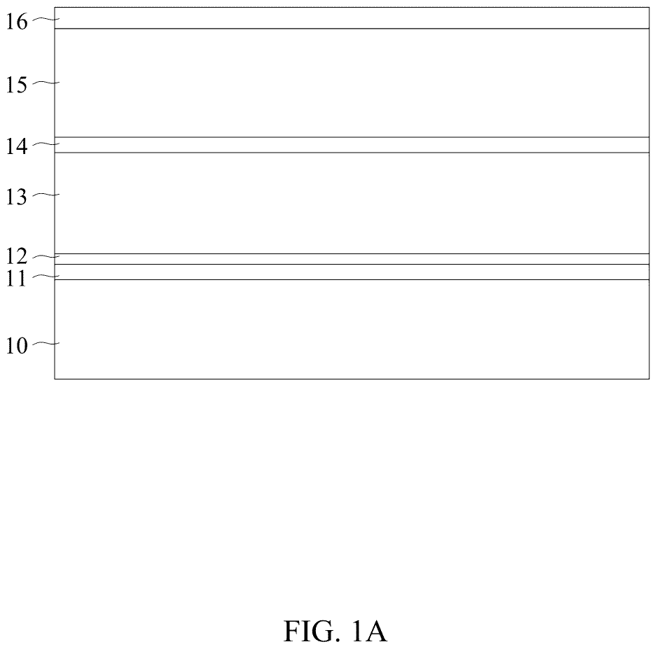

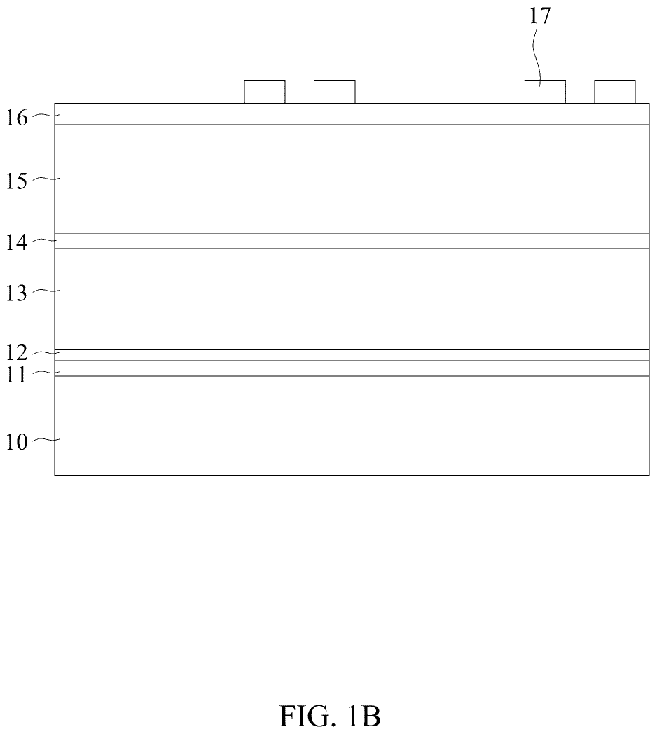

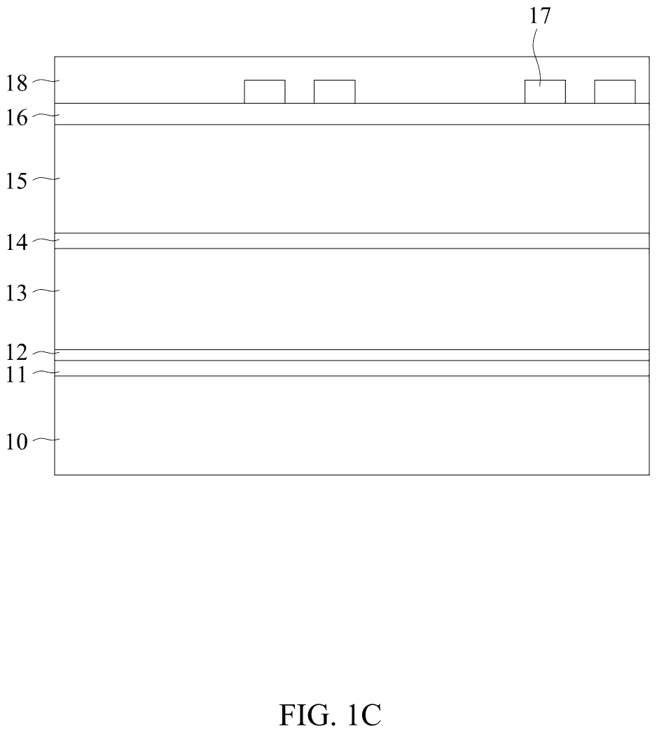

First, prepare a light-emitting diode structure with a first wavelength band, where the first wavelength band may be, for example, but not limited to, 1100˜2000 nanometers (nm). Referring to FIG. 1A, it shows epitaxial growth of a buffer layer 11 and an N-type ohmic contact layer 12 on a first epitaxial growth substrate 10 using metal-organic chemical vapor deposition (MOCVD) or molecular beam epitaxy (MBE) techniques. Specifically, the first epitaxial growth substrate 10 is an indium phosphide (InP) substrate, though not limited thereto. Additionally, the buffer layer 11 is an N-type indium phosphide (InP) epitaxial layer, used to adjust lattice matching between the epitaxial growth substrate and the subsequent epitaxial composite layer for reducing stress due to lattice mismatch in the subsequent epitaxial process and thereby improving the film quality of the subsequent epitaxial layers.

Next, the N-type ohmic contact layer 12 is specifically an N-type indium gallium arsenide (InGaAs) epitaxial layer, with a lattice constant between that of indium phosphide (InP) and a multiple quantum well structure. Thus, the N-type indium gallium arsenide epitaxial layer also serves as a buffer layer for further adjusting lattice matching for subsequent epitaxial layers. Additionally, the N-type indium gallium arsenide epitaxial layer optimizes carrier injection efficiency for adjusting its bandgap based on the gallium-to-indium ratio to control electron and hole transport and to ensure that more carriers are effectively injected into the light-emitting layer for enhancing luminous efficiency. Specifically, the N-type ohmic contact layer 12 serves as an interface for ohmic contact between the device and the N-type electrode. Commonly used dopants in the N-type indium gallium arsenide epitaxial layer include sulfur(S), selenium (Se), or silicon (Si), with a doping concentration typically between 10¹⁸ and 10²⁰ cm⁻³. This concentration range helps reduce the Schottky barrier for achieving low-resistance ohmic contact.

Subsequently, a first epitaxial composite layer is grown on the N-type ohmic contact layer 12, comprising an N-type indium phosphide (InP) epitaxial layer 13, a first light-emitting layer 14, and a P-type indium phosphide epitaxial layer 15. The first light-emitting layer 14 is a multiple quantum well (MQW) structure formed from indium gallium arsenide phosphide (InGaAsP), a quaternary compound semiconductor, interposed between the N-type indium phosphide epitaxial layer 13 and the P-type indium phosphide epitaxial layer 15. In this embodiment, the emission wavelength of the multiple quantum well may range from 1100˜2000 nanometers (nm), preferably 1350 nm, 1450 nm, 1550 nm, or 1600 nm. It should be noted that the materials described in this embodiment are merely examples, and the invention is not limited thereto. In practical applications, materials and their compositions can be adjusted based on the emission wavelength, such as using aluminum indium arsenide (AlInAs) or indium gallium arsenide (InGaAs) for the epitaxial layers.

As shown in FIG. 1A, a compound semiconductor layer is further epitaxially grown on the epitaxial composite layer. In this specific embodiment, this compound semiconductor layer is a P-type zinc-doped indium gallium arsenide phosphide (Zn-doped InGaAsP) epitaxial layer 16 for serving as an ohmic contact layer, with a thickness not exceeding 1 micrometer (μm), preferably 500˜5000 angstroms (Å). Specifically, the doping concentration of this zinc-doped indium gallium arsenide phosphide epitaxial layer is between 10¹⁸ and 10²⁰ cm⁻³, which helps reduce contact resistance to form an ohmic contact with the subsequent metal layer interface.

Next, referring to FIG. 1B, a metal stack 17 is deposited on the P-type zinc-doped indium gallium arsenide phosphide epitaxial layer 16 by evaporation or sputtering. This metal stack 17 specifically is selected from the group consisting of titanium (Ti), platinum (Pt), gold (Au), and combinations thereof, with a thickness less than 1 micrometer, optimally 2000˜5000 angstroms (Å). Then, a patterning process is performed on the metal stack 17 for distributing it appropriately within the first epitaxial composite layer according to the design pattern of the subsequent light-emitting diode electrodes and serving as conductive plugs for uniform vertical current diffusion within the light-emitting diode. Next, referring to FIG. 1C, a first transparent conductive layer 18 is formed on the wafer surface for covering the first epitaxial composite layer. More specifically, the first transparent conductive layer 18 covers the P-type zinc-doped indium gallium arsenide phosphide epitaxial layer 16 and the patterned metal stack 17. The first transparent conductive layer 18 is made of materials such as indium tin oxide (ITO), aluminum zinc oxide (AZO), indium zinc oxide (IZO), nickel oxide, indium tin oxide, cadmium tin oxide, antimony tin oxide, or combinations thereof.

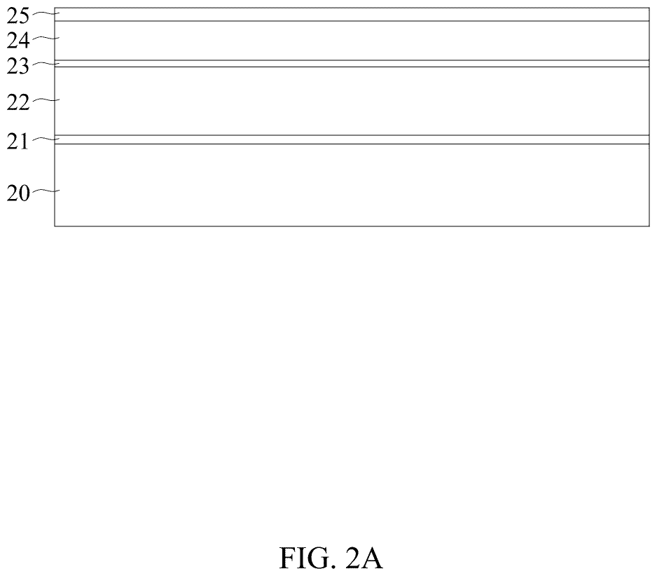

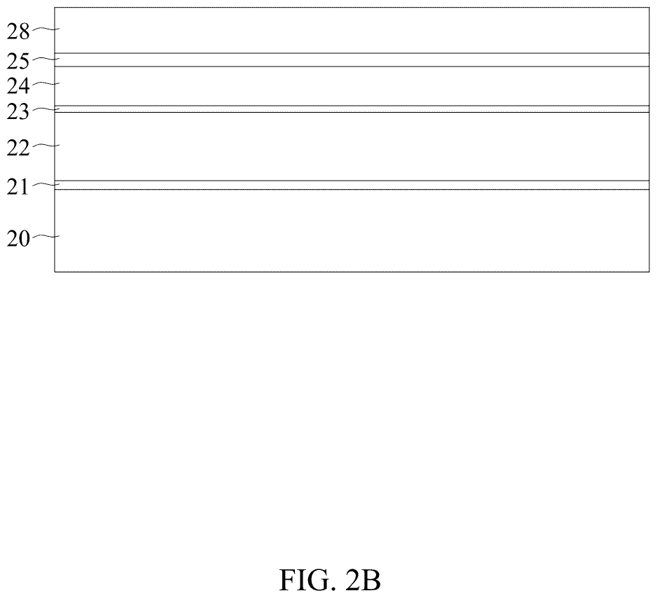

Next, prepare a light-emitting diode structure with a second wavelength band, where the second wavelength band may be, for example, but not limited to, 1000˜1100 nanometers (nm). Referring to FIG. 2A, a gallium arsenide (GaAs) substrate is used as a second epitaxial growth substrate 20. Subsequently, an N-type gallium arsenide layer 21 is formed on the gallium arsenide substrate as a buffer layer. Then, a second epitaxial composite layer, such as a double heterostructure of aluminum gallium arsenide (AlGaAs), is formed on the buffer layer. Specifically, in this embodiment, the second epitaxial composite layer comprises an N-type aluminum gallium arsenide (AlGaAs) epitaxial layer 22, a second light-emitting layer 23, and a P-type aluminum gallium arsenide (AlGaAs) epitaxial layer 24. The second light-emitting layer 23 is a multiple quantum well (MQW) structure made of indium gallium arsenide (InGaAs), with an emission wavelength in this embodiment ranging from 1000˜1100 nanometers (nm). Additionally, in practical applications, the heterostructure epitaxial materials may also include aluminum gallium indium phosphide (AlGaInP), indium gallium phosphide (InGaP), aluminum gallium arsenide (AlGaAs), or indium gallium arsenide (InGaAs). Continuing with FIG. 2A, a P-type carbon-doped gallium arsenide (GaAs) epitaxial layer 25 is formed on the second epitaxial composite layer as a subsequent ohmic contact layer, with a carbon doping concentration of 4×10¹⁹˜1.5×10²⁰ cm⁻³ to reduce contact resistance. Referring to FIG. 2B, a second transparent conductive layer 28 is deposited to cover the P-type carbon-doped gallium arsenide epitaxial layer 25, with the same material composition as the first transparent conductive layer 18 described above.

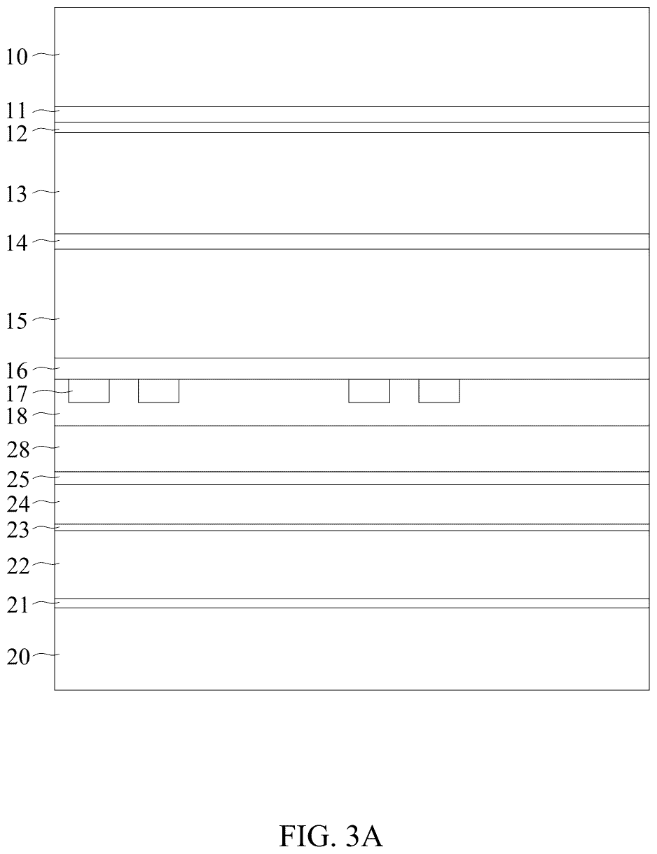

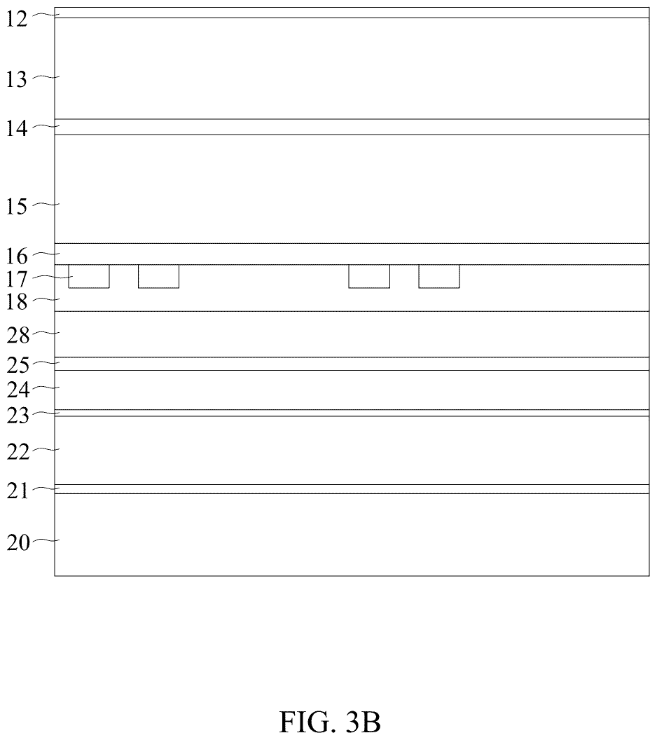

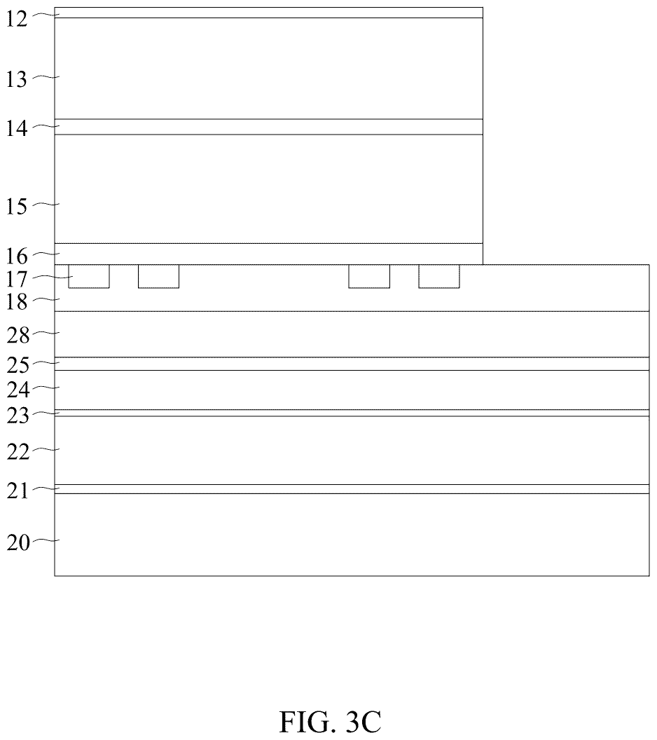

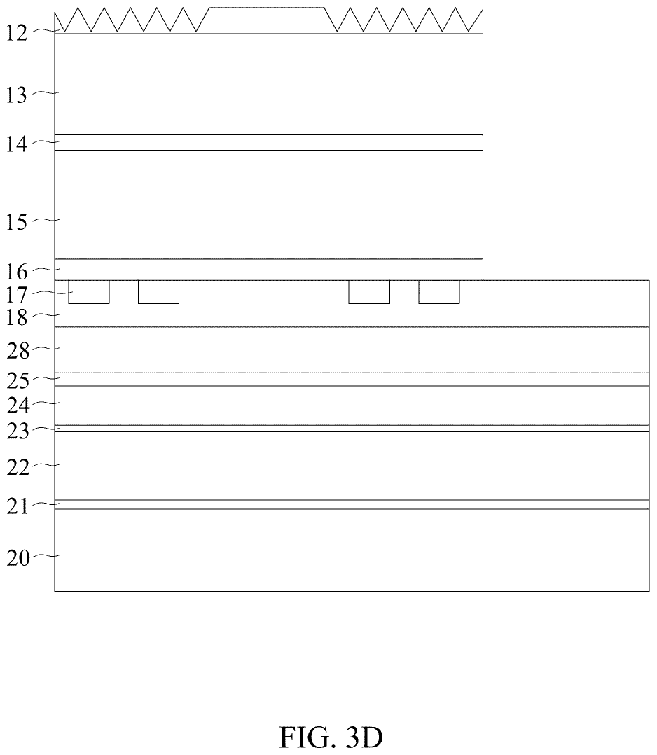

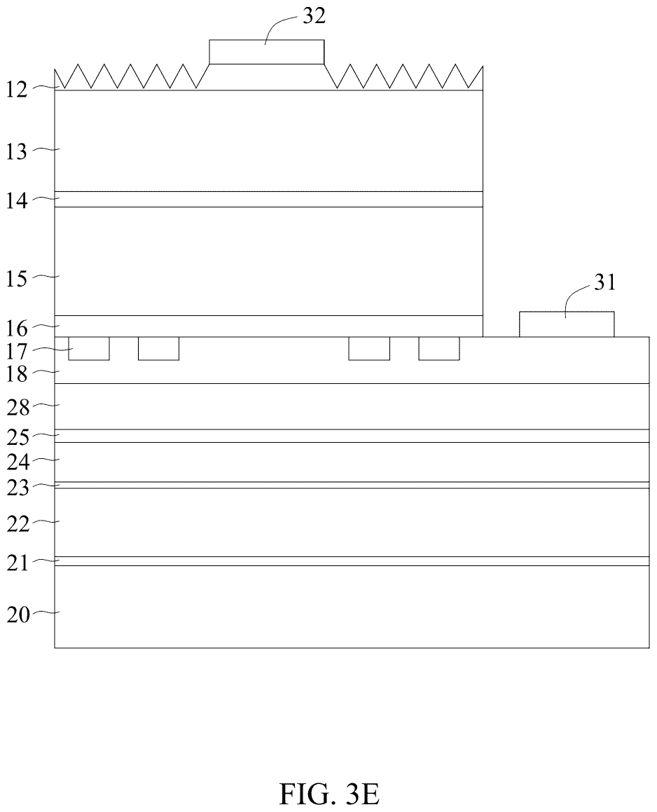

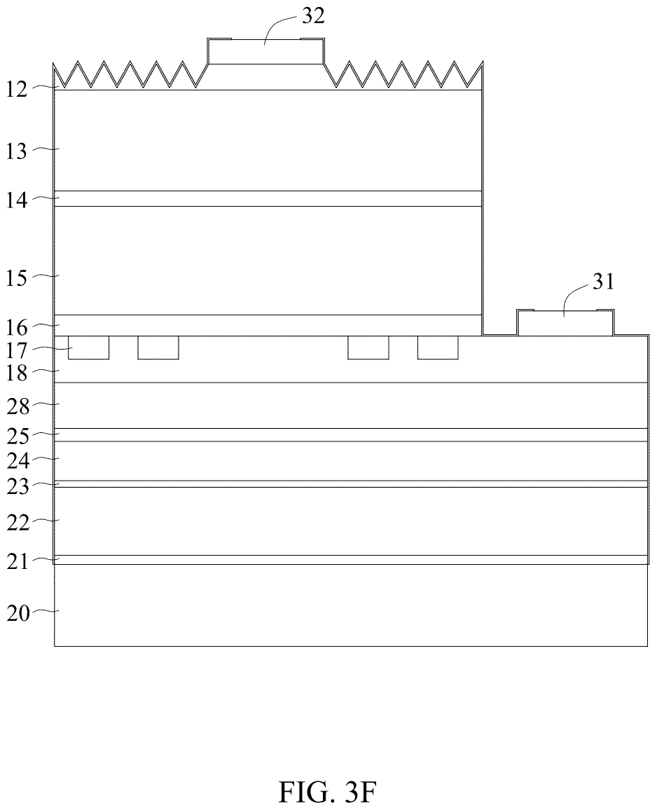

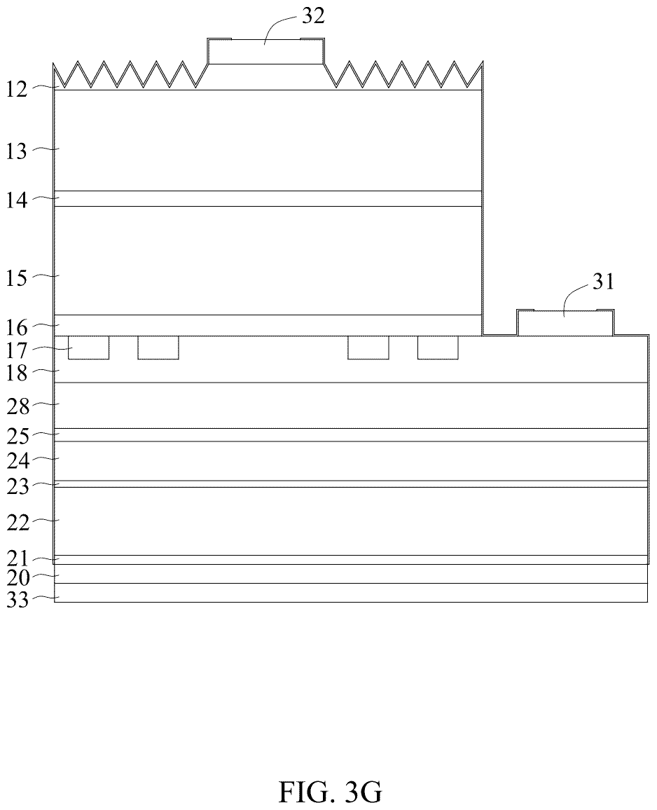

Referring to FIG. 3A, the first transparent conductive layer 18 on the first epitaxial growth substrate 10 is bonded to the second transparent conductive layer 28 on the second epitaxial growth substrate 20 at high temperature using a bonding process for these two wafers to form a single transparent conductive layer with a total thickness preferably controlled at 3000˜10000 angstroms (Å). As shown in FIG. 3A, it is clear that the transparent conductive layer, synthesized from the first transparent conductive layer 18 and the second transparent conductive layer 28, is interposed between the two epitaxial composite layers for enabling the light-emitting diode of the present invention to provide dual-band light. Next, the first epitaxial growth substrate 10 and buffer layer 11 are removed together and flip the second epitaxial growth substrate 20 to be located at the bottom of the dual-band light-emitting diode structure, as shown in FIG. 3B. Subsequently, a mesa etching process is performed for etching portions of the N-type ohmic contact layer 12 and the first epitaxial composite layer to expose a flat surface of the first transparent conductive layer 18 for subsequent P-type electrode placement, as shown in FIG. 3C.

Referring to FIG. 3D, a roughening process is performed on the mesa structure to remove part of the N-type ohmic contact layer 12. Then, a metal evaporation process is conducted to form a P-type electrode 31 on the exposed surface of the first transparent conductive layer 18 and a first N-type electrode 32 on the unroughened N-type ohmic contact layer 12. The P-type electrode 31 may be a metal stack, such as, but not limited to, chromium-gold (CrAu), titanium-gold (TiAu), or chromium-titanium-gold (CrTiAu) stacks for providing good metal adhesion, ohmic contact, and high conductivity for the P-type electrode. The N-type electrode material may be, for example, but not limited to, germanium-gold (GeAu) or germanium-gold-nickel (GeAuNi) stacks for ensuring low contact resistance and good stability for the N-type electrode. Referring to FIG. 3F, a protective layer, such as a silicon dioxide (SiO₂) layer, is formed on the surface of the light-emitting diode device, except for the electrode surfaces intended for metal wire bonding.

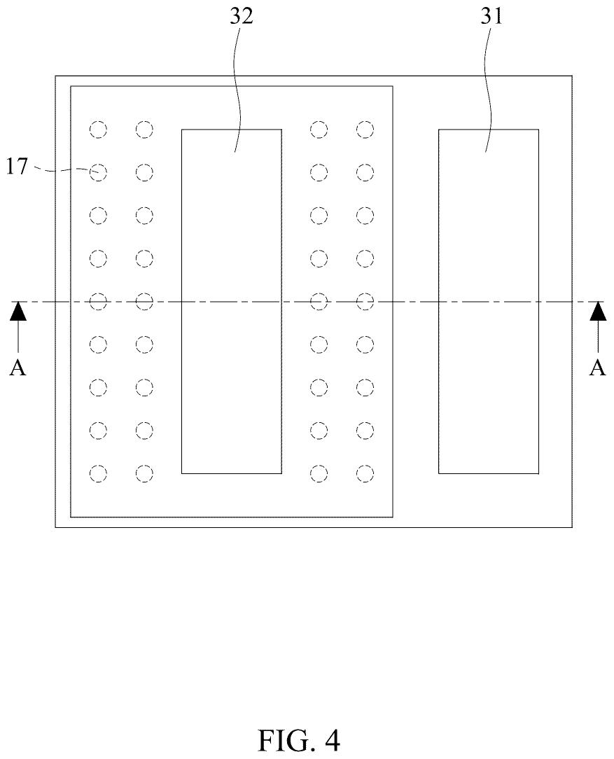

Referring to FIG. 3G, depending on the device design requirements, the second epitaxial growth substrate 20 is thinned, controlling the total height of the final light-emitting diode structure to 100˜200 micrometers, though not limited to this range. For example, the second epitaxial growth substrate 20 may be completely removed for reducing the total height of the light-emitting diode structure to less than 100 micrometers. Finally, a second N-type electrode 33 is formed on the side of the thinned second epitaxial growth substrate 20, with the same material as the first N-type electrode 32, and thus not further elaborated. Referring to FIG. 4, it shows a top-view schematic diagram of a dual-band light-emitting diode according to an embodiment of the present invention. The cross-sectional view along the AA line in FIG. 4 corresponds to the cross-section shown in FIG. 3G, clearly illustrating several metal stacks 17 acting as conductive plugs distributed around the first N-type electrode 32, without overlapping vertically, to effectively diffuse current vertically and avoid current crowding.

It should be particularly noted that the dual-band light-emitting diode disclosed in the present invention has two light-emitting layers with different wavelength bands. When the P-type electrode 31 and the first N-type electrode 32 are activated, current flows through the first transparent conductive layer 18 and the second transparent conductive layer 28 to activate the first light-emitting layer 14 for providing light in the first wavelength band. In this embodiment, this provides near-infrared light in the range of 1100˜2000 nanometers (nm), such as 1350 nm or 1450 nm. On the other hand, when the P-type electrode 31 and the second N-type electrode 33 are activated, current flows through the first transparent conductive layer 18 and the second transparent conductive layer 28 to activate the second light-emitting layer 23 for providing light in the second wavelength band of near-infrared light, such as 1065 nm. When the P-type electrode 31, first N-type electrode 32, and second N-type electrode 33 are activated simultaneously, both the first light-emitting layer 14 and the second light-emitting layer 23 are activated for providing dual-band near-infrared light with both the first and second wavelength bands. This achieves the purpose of providing dual-band light in a single light-emitting diode chip for meeting the needs of wearable devices for compact, multi-band detection components while also reducing related manufacturing costs.

In a preferred embodiment, during device design, the epitaxial layer capable of emitting a longer wavelength band should be arranged at the top of the device structure, while the epitaxial layer emitting a shorter wavelength band should be arranged at the bottom. This ensures that light emitted from the lower light-emitting layer, passing through the upper epitaxial layer, is not absorbed by the smaller-bandgap material above, as short-wavelength light would not be absorbed. Conversely, if the longer-wavelength epitaxial layer were placed at the bottom and the shorter-wavelength layer at the top, the longer-wavelength light emitted from the bottom would be absorbed by the larger-bandgap material arranged above, reducing the luminous efficiency of the light-emitting device.

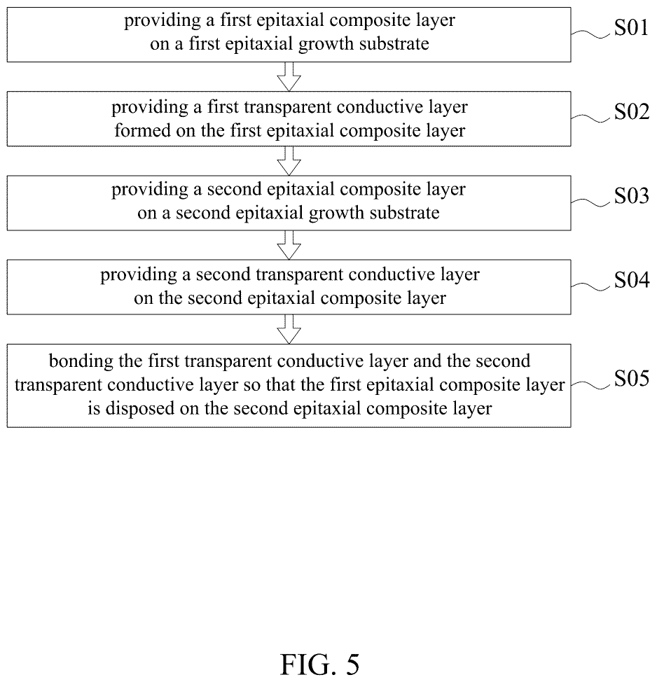

Referring to FIG. 5, it shows a flowchart of the process for manufacturing a dual-band light-emitting diode according to the present invention. First, in step S01, a first epitaxial composite layer is provided on a first epitaxial growth substrate, the first epitaxial composite layer having a first light-emitting layer of a first wavelength band. In step S02, a first transparent conductive layer is provided on the first epitaxial composite layer. Next, in step S03, a second epitaxial composite layer is provided on a second epitaxial growth substrate, the second epitaxial composite layer having a second light-emitting layer of a second wavelength band, wherein the first wavelength band is no less than the second wavelength band. In step S04, a second transparent conductive layer is provided on the second epitaxial composite layer. Finally, in step S05, the first transparent conductive layer and the second transparent conductive layer are bonded, such that the first transparent conductive layer and the second transparent conductive layer are interposed between the first epitaxial composite layer and the second epitaxial composite layer, with the first epitaxial composite layer disposed on the second epitaxial composite layer. For descriptions of the related components in the aforementioned process steps, refer to the content above, which is not repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A dual-band light-emitting diode, comprising:
a first epitaxial composite layer, having a first light-emitting layer of a first wavelength band;
a second epitaxial composite layer, having a second light-emitting layer of a second wavelength band, wherein the first wavelength band is no less than the second wavelength band; and
a transparent conductive layer, interposed between the first epitaxial composite layer and the second epitaxial composite layer, with the first epitaxial composite layer disposed on the second epitaxial composite layer.

2. The dual-band light-emitting diode of claim 1, further comprising a P-type electrode, disposed on the transparent conductive layer, and electrically connected to the transparent conductive layer.

3. The dual-band light-emitting diode of claim 1, further comprising a first N-type electrode and a second N-type electrode, wherein the first N-type electrode is disposed on the first epitaxial composite layer and is electrically connected to the first light-emitting layer, and the second N-type electrode is disposed on the second epitaxial composite layer and is electrically connected to the second light-emitting layer.

4. The dual-band light-emitting diode of claim 1, wherein the first epitaxial composite layer further comprises an N-type indium phosphide epitaxial layer and a P-type indium phosphide epitaxial layer, and the first light-emitting layer is interposed between the N-type indium phosphide epitaxial layer and the P-type indium phosphide epitaxial layer.

5. The dual-band light-emitting diode of claim 4, wherein the first epitaxial composite layer further comprises a P-type zinc-doped indium gallium arsenide epitaxial layer interposed between the P-type indium phosphide epitaxial layer and the transparent conductive layer.

6. The dual-band light-emitting diode of claim 1, wherein the second epitaxial composite layer further comprises an N-type aluminum gallium arsenide epitaxial layer and a P-type aluminum gallium arsenide epitaxial layer, and the second light-emitting layer is interposed between the N-type aluminum gallium arsenide epitaxial layer and the P-type aluminum gallium arsenide epitaxial layer.

7. The dual-band light-emitting diode of claim 6, wherein the second epitaxial composite layer further comprises a P-type carbon-doped gallium arsenide epitaxial layer interposed between the P-type aluminum gallium arsenide epitaxial layer and the transparent conductive layer.

8. The dual-band light-emitting diode of claim 1, wherein the first wavelength band is 1100˜2000 nanometers (nm), and the second wavelength band is 1000˜1100 nanometers (nm).

9. The dual-band light-emitting diode of claim 1, wherein the thickness of the transparent conductive layer is 3000˜10000 angstroms (Å).

10. A manufacturing method of a dual-band light-emitting device, comprising:
providing a first epitaxial composite layer on a first epitaxial growth substrate, the first epitaxial composite layer having a first light-emitting layer of a first wavelength band;
providing a first transparent conductive layer formed on the first epitaxial composite layer;
providing a second epitaxial composite layer on a second epitaxial growth substrate, the second epitaxial composite layer having a second light-emitting layer of a second wavelength band, wherein the first wavelength band is no less than the second wavelength band; and
providing a second transparent conductive layer formed on the second epitaxial composite layer; and
bonding the first transparent conductive layer and the second transparent conductive layer so the first transparent conductive layer and the second transparent conductive layer are interposed between the first epitaxial composite layer and the second epitaxial composite layer, with the first epitaxial composite layer disposed on the second epitaxial composite layer.

11. The manufacturing method of a dual-band light-emitting diode of claim 10, further comprising a step of performing a mesa etching on the first epitaxial composite layer to expose a portion of the first transparent conductive layer after removing the first epitaxial growth substrate.

12. The manufacturing method of a dual-band light-emitting diode of claim 11, further comprising a step of providing a P-type electrode, disposed on the exposed first transparent conductive layer, and electrically connected to the first transparent conductive layer and the second transparent conductive layer.

13. The manufacturing method of a dual-band light-emitting diode of claim 11, further comprising a step of providing a first N-type electrode, disposed on the first epitaxial composite layer and electrically connected to the first light-emitting layer.

14. The manufacturing method of a dual-band light-emitting diode of claim 10, further comprising a step of thinning the second epitaxial growth substrate.

15. The manufacturing method of a dual-band light-emitting diode of claim 14, further comprising a step of providing a second N-type electrode, disposed on the thinned second epitaxial composite layer and electrically connected to the second light-emitting layer.

16. The manufacturing method of a dual-band light-emitting diode of claim 10, wherein the step of providing a first epitaxial composite layer formed on a first epitaxial growth substrate is to sequentially provide an N-type indium phosphide (InP) epitaxial layer, the first light-emitting layer and a P-type indium phosphide epitaxial layer on an indium phosphide substrate.

17. The manufacturing method of a dual-band light-emitting diode of claim 10, wherein the step of providing a second epitaxial composite layer formed on a second epitaxial growth substrate is to sequentially provide an N-type aluminum gallium arsenide (AlGaAs) epitaxial layer, the second light-emitting layer and a P-type aluminum gallium arsenide epitaxial layer on a gallium arsenide substrate.

18. The manufacturing method of a dual-band light-emitting diode of claim 10, wherein the first wavelength band is 1100˜2000 nanometers (nm), and the second wavelength band is 1000˜1100 nanometers (nm).

19. The manufacturing method of a dual-band light-emitting diode of claim 10, wherein the total thickness of the first transparent conductive layer and the second transparent conductive layer is 3000˜10000 angstroms (Å).
